(19) United States
(12) Patent Application Publication
(10) Pub. No.: US 2010/0037119 A1
(43) Pub. Date: Feb. 11, 2010

(54) APPARATUS AND METHOD FOR UPDATING CHECK NODE OF LOW-DENSITY PARITY CHECK CODES

(76) Inventors: Jong-Ee Oh, Daejeon-City (KR); Yu-Ro Lee, Daejeon-city (KR); Chanho Yoon, Daejeon-city (KR); Minho Cheong, Daejeon-city (KR); Sok-Kyu Lee, Daejeon-city (KR); Yoo-Seung Song, Gyeonggi-do (KR); Younggyun Kim, Laguna Hills, CA (US)

Correspondence Address: STAAS & HALSEY LLP, SUITE 700, 1201 NEW YORK AVENUE, N.W., WASHINGTON, DC, 20005, US

(21) Appl. No.: 12/517,455

(22) PCT Filed: Dec. 5, 2007
(86) PCT No.: PCT/KR07/06277

§ 371 Date: Jun. 3, 2009

(30) Foreign Application Priority Data
Dec. 5, 2006 (KR) 10-2006-0122557
Jul. 20, 2007 (KR) 10-2007-0073098

(51) Int. Cl. H03M 13/05; G06F 11/10

(52) U.S. Cl. 714/752; 714/E11.032

(57) ABSTRACT

An apparatus and method for updating a check node of a low-density parity check (LDPC) code in order to decode the LDPC code are provided. The method includes the operations of: (a) obtaining a first bit of a first minimum value among input values, the number of input values being equal to the number of degrees of the check node, by performing an AND operation on first bits of the input values, the first bits being most significant bits of the input values; (b) obtaining result values by switching and sequentially performing an XOR operation and an OR operation on the first bit of the first minimum value and each of the first bits of the input values; and (c) performing operations (a) and (b) on the result values set as input values and performing operations (a) and (b) a number of times corresponding to the number of bits of each input value, that is, repeating until last bits are set as input values, to thereby obtain the first minimum value, the last bits being least significant bits of the input values. Accordingly, the complexity of hardware is reduced, and super high-speed processing is possible.

### CROSS-REFERENCE TO RELATED PATENT APPLICATION

This application claims the benefits of Korean Patent Application No. 10-2006-0122557, filed on Dec. 05, 2006, and Korean Patent Application No. 10-2007-0073098, filed on Jul. 20, 2007, in the Korean Intellectual Property Office, the disclosures of which are incorporated herein in their entirety by reference.

### BACKGROUND OF THE INVENTION

1. Field of the Invention

The present invention relates to error correction codes for use in a wired/wireless communications system, and more particularly, to an apparatus and method for updating check nodes of low-density parity check (LDPC) codes.

This work was supported by the IT R&D program of MIC/IITA [2007-S001-01, IMT-Advanced Radio Transmission Technology with Low Mobility]

2. Description of the Related Art

Signals transmitted by a wired/wireless communications system may not be demodulated in a receiver due to noise, interference, or fading according to the state of a channel.

Several methods are used to reduce an error generation rate that increases with high-speed communications. These methods include a method of using error correction codes.

Most recent wireless communications systems use error correction codes. In particular, low-density parity check (LDPC) codes are receiving much attention as error correction codes for next-generation high-capacity wireless communications systems, because variable nodes and check nodes of a decoder can be implemented to have low complexity and a decoder can achieve fast decoding by employing a parallel processing technique.

LDPC codes have been proposed by Gallager, and are defined by a sparse parity check matrix. Most of the elements of the sparse parity check matrix are 0 and a very small number of elements are 1.

There are two basic classes of the LDPC codes proposed by Gallager. Regular LDPC codes have a constant number of ones in every column or row of a parity check matrix. With irregular LDPC codes, the number of ones varies from row to row and column to column.

It is generally known that irregular LDPC codes provide better performance than regular LDPC codes.

Conventional techniques for updating check nodes will now be described.

Equation 1 below is a variable node updating equation of a Sum-Product algorithm for use in decoding LDPC codes:

$${v}_{j} = {\sum }_{i = 0 , i \neq j}^{{d}_{v}} {u}_{i + {LLR}_{channel}} \qquad ( Equation 1 )$$

where LLR_{channel} denotes an input log likelihood ratio (LLR) obtained by a demodulator, dᵥ denotes the degree of a variable node, uᵢ denotes an i-th input LLR of the variable node, and vⱼ denotes a j-th output LLR of the variable node.

The update of a variable node is represented as a sum of input values and thus hardware can be implemented by simply subtracting a specific value of the check node from a sum of dᵥ inputs. Equation 2 below is a check node updating equation of a Sum-Product algorithm:

$$tanh \frac{{u}_{i}}{2} = {{X}^{{d}_{c}}}_{j = 1 , j \neq i} tanh \frac{{v}_{j}}{2} \qquad ( Equation 2 )$$

wherein d_{c} denotes the degree of a check node, vⱼ denotes a j-th input LLR of the check node, and uᵢ denotes an i-th output LLR of the check node.

The update of a check node is represented as a sum of hyperbolic tangent values of input values and thus is difficult to be implemented by hardware.

Accordingly, several methods of lowering the complexity of variable nodes and check nodes of a decoder have been proposed. One of these methods can be represented as Equation 3, which is the logarithm of Equation 2:

$$log ( tanh \frac{{u}_{i}}{2} ) = {\sum }_{j = 1 , j \neq i}^{{d}_{c}} log ( tanh \frac{{v}_{j}}{2} ) \qquad ( Equation 3 )$$

According to Equation 3, multiplication is not needed when updating a check node, but Equation 3 should be calculated using a look-up table or the like as in Equation 2. Instead of such a complex process, a check node updating method has been proposed, which slightly degrades the performance and is represented as Equation 4:

$${u}_{i} = ( {{X}^{{d}_{c}}}_{j = 1 , j \neq i} sgn ( {v}_{j} ) ) {{min}^{{d}_{c}}}_{j = 1 , j \neq i} \vert {v}_{j} \vert \qquad ( Equation 4 )$$

wherein sgn denotes a function of outputting +1 when an input is positive and outputting −1 when an input is negative, and min denotes a function of outputting a minimum input value among various input values. Equation 4 represents a Min-Sum algorithm.

Equation 5, representing a normalized Min-Sum algorithm, is as follows:

$${u}_{i} = ( {{X}^{{d}_{c}}}_{j = 1 , j \neq i} sgn ( {v}_{j} ) ) {{min}^{{d}_{c}}}_{j = 1 , j \neq i} ( α \cdot \vert {v}_{j} \vert ) \qquad ( Equation 5 )$$

wherein α denotes a normalization value.

Equation 6, representing an offset Min-Sum algorithm, is as follows:

$${u}_{i} ( {{X}^{{d}_{c}}}_{j = 1 , j \neq i} sgn ( {v}_{j} ) ) {{min}^{{d}_{c}}}_{j = 1 , j \neq i} ( min ( \vert {v}_{j} \vert - β , 0 ) ) \qquad ( Equation 6 )$$

wherein β denotes an offset.

Although Equations 4, 5, and 6 have slight differences therebetween, they can be processed by performing an XOR operation on the sign of an output and obtaining a first minimum value and a second minimum value from d_{c} absolute input values. Therefore, Equations 4, 5, and 6 can provide easier hardware implementations than the other equations.

### SUMMARY OF THE INVENTION

The present invention provides an apparatus and method for obtaining a first minimum value and a second minimum value among several input values while linearly increasing only the complexity of calculation with an increase in the degree of a check node and not increasing the speed of parallel processing when parallel processing is used.

The present invention also provides an apparatus and method for obtaining a first minimum input value and a second minimum input value among several input values while linearly increasing only the complexity of calculation with an increase in the degree of a check node and not increasing the processing speed when a check node of a low density parity check (LDPC) code is implemented. This method is applicable to a technique of using a Min-Sum algorithm, an Offset Min-Sum algorithm, or a Normalized Min-Sum algorithm during the update of a check node of a LDPC decoder in environments that require a fast processing decoder.

Generally, even in an irregular LDPC code, at most about 12 dᵥ values (i.e., at least about two dᵥ values and about 3 to 4 dᵥ values on the average), and thus the complexity of implementation of a variable node is not high.

However, the number of degrees of a check node increases with an increase in the code rate, and thus in IEEE 802.16e or 802.11n, a check node of a LDPC code having an error rate of ⅚ has an average of about 20 degrees.

Additionally, when a very high code rate, such as a code rate of 8/9, is used, the average number of degrees of a check node may be about 30. When a check node has a very large number of degrees as described above, a method of obtaining a minimum value by repeating a method of comparing two input values with each other and leaving a smaller input value may be inefficient.

In a method of updating a check node while preventing an inefficient search for a minimum value according to the present invention, a first minimum input value is found by obtaining a most significant bit (MSB) of the minimum value from MSBs of respective input values and a least significant bit (LSB) of the minimum value from LSBs of the respective input values.

The present invention also provides the use of a single apparatus both when a first minimum input value and a second minimum input value for each of a part and another part of a check node are obtained using a row split process and when a first minimum input value and a second minimum input value for the entire check node are obtained using a row split process.

According to an aspect of the present invention, there is provided a method of updating a check node of an LDPC code in order to decode the LDPC code, the method comprising: (a) obtaining a first bit of a first minimum value among input values, the number of input values being equal to the number of degrees of the check node, by performing an AND operation on first bits of the input values, the first bits being most significant bits of the input values; (b) obtaining result values by switching and sequentially performing an XOR operation and an OR operation on the first bit of the first minimum value and each of the first bits of the input values; and (c) performing operations (a) and (b) on the result values set as input values and performing operations (a) and (b) a number of times corresponding to the number of bits of each input value, that is, repeating until last bits are set as input values, to thereby obtain the first minimum value, the last bits being least significant bits of the input values.

The first minimum value is set as a maximum input value, and a second minimum value is obtained by repeating operations (a), (b), and (c).

The operations (a), (b), and (c) are repeated until a number of minimum values corresponding to the number of degrees of the check node are obtained.

When the check node is a check node for a row-split parity check matrix, operations (a), (b), and (c) are repeated until a number of minimum values corresponding to the number of degrees of each of the check node and another check node for a row-split parity check matrix are obtained.

When the input values are 4-bit input values, operation (a) comprises obtaining the first bit of the first minimum input value among the 4-bit input values by performing an AND operation on the first bits of the 4-bit input values, the first bits being most significant bits of the 4-bit input values, and operation (b) comprises obtaining first result values by sequentially performing an XOR operation and an OR operation on the first bit of the first minimum value, and each of the first bits of the 4-bit input values and obtaining second result values by switching the 4-bit input values to the first result values.

The operation (c) comprises: (c1) obtaining a second bit of the first minimum value among the 4-bit input values by performing an AND operation on second bits of the second result values; and (c2) obtaining third result values by sequentially performing an XOR operation and an OR operation on the second bit of the first minimum input value and the second bit of each of the second result values, and obtaining fourth result values by switching the second result values to the third result values.

The operation (c) further comprises: (c3) obtaining a third bit of the first minimum value among the 4-bit input values by performing an AND operation on third bits of the fourth result values; and (c4) obtaining fifth result values by sequentially performing an XOR operation and an OR operation on the third bit of the first minimum value and the third bit of each of the fourth result values, and obtaining sixth result values by switching the fourth result values to the fifth result values.

The operation (c) further comprises: (c5) obtaining a fourth bit of the first minimum value among the 4-bit input values by performing an AND operation on fourth bits of the sixth result values; and (c6) obtaining seventh result values by sequentially performing an XOR operation and an OR operation on the fourth bit of the first minimum value and the fourth bit of each of the sixth result values, and obtaining eighth result values by switching the sixth result values to the seventh result values.

The operation (c) further comprises (c7) obtaining the first minimum value by performing an AND operation on the first, third, fifth, and seventh result values.

The method further comprises (d) obtaining a second minimum value by setting as 4-bit input values, the number of 4-bit input values being equal to the number of degrees of the check node in operation (a), values obtained by switching the 4-bit input values to results of NOT operations performed on the first minimum value and by re-performing operations (a), (b), and (c).

When the check node is a check node for a row-split parity check matrix, the method further comprises: obtaining a first minimum value and a second minimum value among 4-bit input values for another row-split check node, the number of 4-bit input values equal to the number of degrees of the another row-split check node, by performing operations (a), (b), and (c) on the 4-bit input values; and obtaining a minimum value for each of the two check nodes from the first and second minimum values among the 4-bit input values for each of the two check nodes.

According to another aspect of the present invention, there is provided an apparatus for updating a check node of an LDPC code in order to decode the LDPC code, the apparatus comprising a first bit processor, a second bit processor, a third bit processor, a fourth bit processor, and a bit minimum value calculator. The first bit processor obtains a first bit of a first minimum input value among 4-bit input values, the number of which is equal to the number of degrees of the check node, by performing an AND operation on first bits of the 4-bit input values, the first bits being MSBs of the 4-bit input values, obtains first result values by sequentially performing an XOR operation and an OR operation on the first bit of the first minimum value and each of the first bits of 4-bit input values, and obtains second result values by switching the 4-bit input values to the first result values. The second bit processor obtains a second bit of the first minimum value among the 4-bit input values by performing an AND operation on second bits of the second result values, obtains third result values by sequentially performing an XOR operation and an OR operation on the second bit of the first minimum value and the second bit of each of second result values, and obtains fourth results by switching the second result values to the third result values. The third bit processor obtains a third bit of the first minimum value among the 4-bit input values by performing an AND operation on third bits of the fourth result values, obtains fifth result values by sequentially performing an XOR operation and an OR operation on the third bit of the first minimum value and the third bit of each of the fourth result values, and obtains sixth result values by switching the fourth result values to the fifth result values. The fourth bit processor obtains a fourth bit of the first minimum input value among the 4-bit input values by performing an AND operation on fourth bits of the sixth result values, obtains seventh result values by sequentially performing an XOR operation and an OR operation on the fourth bit of the first minimum value and the fourth bit of each of the sixth result values, and obtains eighth result values by switching the sixth result values to the seventh result values. The bit minimum value calculator obtains the first minimum value by performing an AND operation on the first, third, fifth, and seventh result values.

A second minimum value is obtained by setting, as the 4-bit input values in the first bit processor, values obtained by switching the 4-bit input values to results of NOT operations performed on the first minimum value obtained in the bit minimum value calculator.

The apparatus further comprises a node minimum value calculator which, when the check node is a check node for a row-split parity check matrix, calculates a minimum value for each of the check node and another row-split check node by using first and second minimum values of 4-bit input values for each of the two check nodes, wherein the first and second minimum values of the 4-bit input values for the another check node, the number of which is equal to the number of degrees of the another row-split check node, are obtained by setting the 4-bit input values as the input values of the first bit processor.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates a factor structure of a low-density parity check (LDPC) code designed so that a check node with a degree of 24 can be row-split into two check nodes R1 and R2 each having a degree of 12;

FIG. 2 illustrates an arithmetic operational block for obtaining sign bits in the LDPC code illustrated in FIG. 1;

FIG. 3 illustrates an arithmetic operational block for obtaining a first minimal value and a second minimal value in the LDPC code illustrated in FIG. 1;

FIG. 4 illustrates an arithmetic operational block for obtaining a first minimal value and a second minimal value in a LDPC code designed so that a check node with a degree of 24 can be row-split into two check nodes R1 and R2 each having a degree of 12, according to an embodiment of the present invention;

FIG. 5 is a flowchart illustrating a method of updating a check node for a LDPC code, according to an embodiment of the present invention; and

FIG. 6 is a flowchart illustrating a method of updating a check node for a LDPC code when a number of input values equal to the number of degrees of the check node are 4-bit input values, according to an embodiment of the present invention.

### DETAILED DESCRIPTION OF THE INVENTION

The present invention will now be described more fully with reference to the accompanying drawings, in which exemplary embodiments of the invention are shown.

In order to implement a decoder for low-density parity check (LDPC) codes, log likelihood ratio (LLR) values which are transmitted through edges need to be quantized and represented with x bits.

A quantization technique and the number of bits used affect the performance and complexity of the decoder for LDPC codes. When a normalization Min-Sum method is used, the value of a normalization factor a also affects the performance of the decoder for LDPC codes. When an offset Min-Sum method is used, the value of an offset β also affects the performance of the decoder for LDPC codes.

A method of decoding LDPC codes according to the present invention is applicable to a Min-Sum method, a normalization Min-Sum method, and an offset Min-Sum method regardless of quantization techniques and parameter values. However, an application of the method of the present invention to an offset Min-Sum method will be illustrated. A similar extensive application of the present invention to the other methods can be easily performed, and a change to a block for performing a function similar to the update of a check node in a LDPC decoder can also be easily made.

The present invention will be described in terms of two cases, namely, when a check node has a degree of 24 and when the check node with a degree of 24 is row split into two check nodes each having a degree of 12. Here, the number of parity bits of a parity check matrix when a row split has occurred is double the number of parity bits of a parity check matrix when a row split has not occurred.

A case where 5 bits are used as quantization bits of a message will be considered. In this case, in order to update check nodes, one bit is used as a sign bit and four bits are used as magnitude bits.

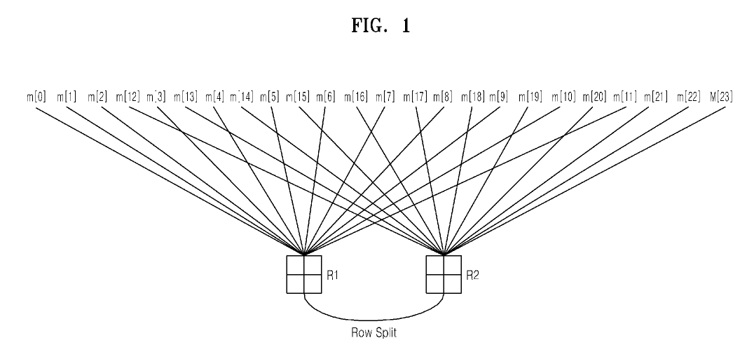

FIG. 1 illustrates a factor structure of a conventional LDPC code designed so that a check node with a degree of 24 can be row split into two check nodes R1 and R2 each having a degree of 12.

In FIG. 1, when a row split is applied, two check nodes are formed. When a row split is not applied, a single check node remains.

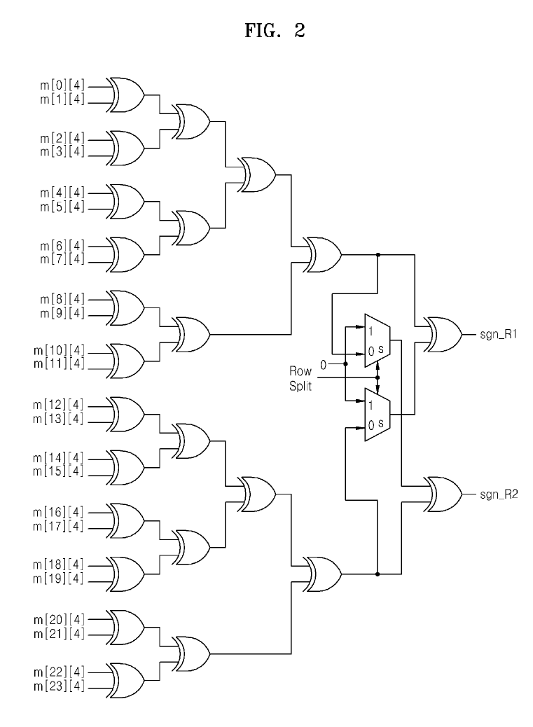

FIG. 2 illustrates an arithmetic operational block for obtaining sign bits in the conventional LDPC code illustrated in FIG. 1.

It is assumed that an input value m[i] input to the arithmetic operational block uses 5 bits and a most significant bit (MSB) m[i][4] is used as a sign bit.

When a row split is not applied, parity bits of R1 and R2, sgn_R1 and sgn_R2, have the same value. An output sign bit can be obtained by performing an XOR operation on the sgn_R1 and each of MSBs m[0][4] through m[11][4] of 5-bit input values, and an output sign bit can be obtained by performing an XOR operation on the sgn_R2 and each of MSBs m[12][4] through m[23][4].

The above-described sign bit obtainment performed in the arithmetic operational block is widely used due to its simplicity. Accordingly, the present invention uses this sign bit obtainment.

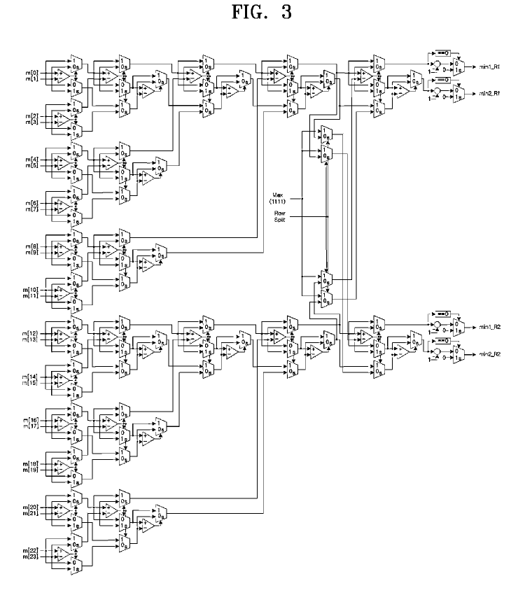

FIG. 3 illustrates an arithmetic operational block for obtaining a first minimal value and a second minimal value among input values in the conventional LDPC code illustrated in FIG. 1.

Referring to FIG. 3, an input value m[i] input to the arithmetic operational block represents 4 magnitude bits excluding a MSB representing a sign among 5 bits.

In FIG. 3, a quantization step 1 is used as an offset value β of the offset Min-Sum algorithm, and the arithmetic operational block is designed so as to repeat a function of obtaining the first and second minimal values among four input values.

When a row split is not applied, first minimal values of R1 and R2, min1_R1 and min1_R2, have the same value, and second minimal values of R1 and R2, min2_R1 and min2_R2, have the same value.

When min1_R1 is equal to each of input values m[0] through m[11], min2_R1 is determined as an output magnitude. On the other hand, when min1_R1 is different from each of the input values m[0] through m[11], min1_R1 is determined as an output magnitude. When min1_R2 is equal to each of input values m[12] through m[23], min2_R2 is determined as an output magnitude. On the other hand, when min1_R2 is different from each of the input values m[12] through m[23], min1_R2 is determined as an output magnitude.

In the arithmetic operational block illustrated in FIG. 3, the number of comparison operations increases with an increase in the number of inputs. According to FIG. 3, 16 4-bit comparators are needed for 12 inputs during 17 stages.

In particular, the row degree of a LDPC code increases with an increase in a code rate, and thus a method of more efficiently processing the method of obtaining the first and second minimal values is needed.

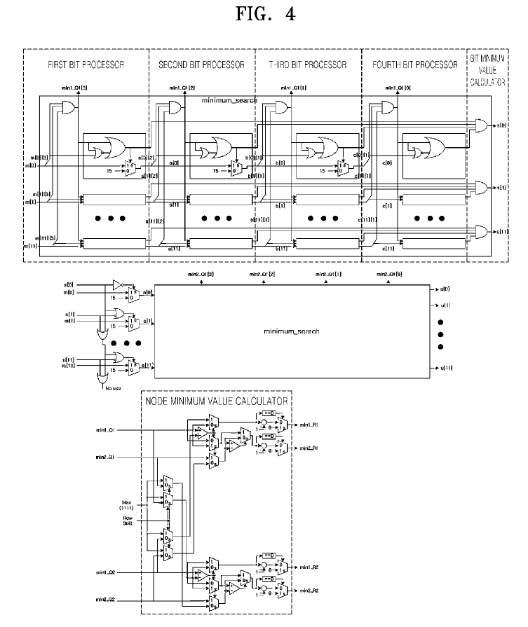

FIG. 4 illustrates an arithmetic operational block for obtaining a first minimal input value and a second minimal input value in a LDPC code designed so that a check node with a degree of 24 can be row-split into two check nodes R1 and R2 each having a degree of 12, according to an embodiment of the present invention. Referring to FIG. 4, the arithmetic operational block according to the current embodiment of the present invention includes a first bit processor, a second bit processor, a third bit processor, a fourth bit processor, a bit minimum value calculator, and a node minimum value calculator.

Each of the first through fourth bit processors, the bit minimum value calculator, and the node minimum value calculator includes logic operators and processes a digital signal representing each input value.

The first bit processor obtains a first bit of a first minimum input value among 4-bit input values, the number of which is equal to the number of degrees of the check node, by performing an AND operation on first bits of the 4-bit input values, the first bits being MSBs of the 4-bit input values, obtains first result values by sequentially performing an XOR operation and an OR operation on the first bit of the first minimum value and each of the first bits of 4-bit input values, and obtains second result values by switching the 4-bit input values to the first result values.

The second bit processor obtains a second bit of the first minimum value among the 4-bit input values by performing an AND operation on second bits of the second result values, obtains third result values by sequentially performing an XOR operation and an OR operation on the second bit of the first minimum value and the second bit of each of second result values, and obtains fourth results by switching the second result values to the third result values.

The third bit processor obtains a third bit of the first minimum value among the 4-bit input values by performing an AND operation on third bits of the fourth result values, obtaining fifth result values by sequentially performing an XOR operation and an OR operation on the third bit of the first minimum value and the third bit of each of the fourth result values, and obtaining sixth result values by switching the fourth result values to the fifth result values.

The fourth bit processor obtains a fourth bit of the first minimum input value among the 4-bit input values by performing an AND operation on fourth bits of the sixth result values, obtains seventh result values by sequentially performing an XOR operation and an OR operation on the fourth bit of the first minimum value and the fourth bit of each of the sixth result values, and obtains eighth result values by switching the sixth result values to the seventh result values.

The bit minimum value calculator obtains the first minimum value by performing an AND operation on the first, third, fifth, and seventh result values.

When the check node is for a row-split parity check matrix, the node minimum value calculator calculates a minimum value for each of the check node and another row-split check node by using first and second minimum input values of 4-bit input values for each of the two check nodes. The first and second minimum input values of the 4-bit input values for the latter check node, the number of 4-bit input values being equal to the number of degrees of the latter row-split check node, are obtained by setting the 4-bit input values as the input values of the first bit processor and performing the operations of the first through fourth bit processors and the bit minimal value calculator on the 4-bit input values.

Referring to FIG. 4, an input value m[i] represents four magnitude bits excluding a MSB representing a sign among five bits. A method of obtaining a first bit min1_Q1[3] of a first minimum input value among 12 input values for the check node R1 by using a quantization step 1 as an offset β of the offset Min-Sum algorithm and by using first bits m[0][3] through m[11][3] is performed on a second bit to a least significant bit (LSB), thereby obtaining a first bit of the first minimum value, min1_Q1, the input value m[i] corresponding to the min1_Q1 is set to be a maximum input value, and the above-described method of obtaining the minimum value is performed again, thereby obtaining a second bit of the first minimum value, min2_Q1.

Although only a method of obtaining the minimum input value for the check node RI has been explained with reference to FIG. 4, min1_Q2 and min2_Q2 for the check node R2 can also be obtained by applying the above-described method of obtaining the minimum value to input values m[12] through m[23] for the check node R2. As illustrated in FIG. 3, a row-split check node is input, and output values for 24 input values of the check node can be obtained.

When row split is not applied, min1_R1 and min1_R2 have an identical value, and min2_R1 and min2_R2 have an identical value. When min1_R1 is equal to each of input values m[0] through m[11], min2_R1 is determined as an output magnitude. On the other hand, when min1_R1 is different from each of the input values m[0] through m[11], min1_R1 is determined as an output magnitude. When min1_R2 is equal to each of input values m[12] through m[23], min2_R2 is determined as an output magnitude. On the other hand, when min1_R2 is different from each of the input values m[12] through m[23], min1_R2 is determined as an output magnitude.

When describing the method explained with reference to FIG. 4 in greater detail, an AND operation is performed on first bits (i.e., MSBs) m[0][3], m[1][3], . . . , and m[11][3] of 12 4-bit input values m[0], m[1], . . . , and m[11] in order to obtain a first bit min1_Q1[3] of a first minimum input value among the 12 4-bit input values. Results values x1[i] are obtained by sequentially performing an XOR operation and an OR operation on min1_Q1[3] and m[i][3], and values a[i] are obtained by switching min1_Q1[3] to x1[i].

Next, similar to the above-described process, an AND operation is performed on second bits a[0][2], a[1][2], . . . , and a[11][2] of 12 4-bit input values a[0], a[1], . . . , and a[11] in order to obtain a second bit min1_Q1[2] of the first minimum input value. Results values x2[i] are obtained by sequentially performing an XOR operation and an OR operation on min1_Q1[2] and a[i][2], and values b[i] are obtained by switching min1_Q1[2] to x2[i].

Next, similar to the above-described process, an AND operation is performed on third bits b[0][1], b[1][1], . . . , and b[11][1] of 12 4-bit input values b[0], b[1], . . . , and b[11] to obtain a third bit min1_Q1[1] of the first minimum input value. Results values x3[i] are obtained by sequentially performing an XOR operation and an OR operation on min1_Q1[1] and b[i][1], and values c[i] are obtained by switching min1_Q1[1] to x3[i].

Next, similar to the above-described process, an AND operation is performed on fourth bits c[0][0], c[1][0], . . . , and c[11][0] of 12 4-bit input value c[0], c[1], . . . , and c[11] in order to obtain a fourth bit min1_Q1[0] of the first minimum input value, and results values x4[i] are obtained by sequentially performing an XOR operation and an OR operation on min1_Q1[0] and c[i][1].

An AND operation is performed on results x1[i], x2[i], x3[i], and x4[i] to thereby obtain each bit s[i] of the first minimum value.

The above description is about a first minimum search block shown on the top of FIG. 4.

A e[i]value is calculated using the thus-calculated values s[i] and m[i], and is input to a second minimum search block below the first minimum search block shown on the top of FIG. 4, thereby obtaining first through fourth bits min2_Q1[3], min2_Q1[2], min2_Q1[1], and min2_Q1[0] of a second minimum input value among the 12 4-bit input values m[0], m[1], . . . , and m[11]. The first and second minimum search blocks perform the same minimum search operations.

A node minimal value calculation block below the second minimum search block performs its operation on min1_Q2 and min2_Q2, which are obtained according to the same method as the method of obtaining the values min1_Q1, min2_Q1.

As compared with FIG. 3, the method described with reference to FIG. 4 is characterized in that no comparators are used during the search for the first and second minimum input values from the 12 input values. Therefore, the minimum value search according to the present invention can be performed fast. In particular, when the number of input bits is small, the speed of the minimum value search is increased.

Even when about 4 bits are used as magnitude bits when regular quantization is used, and about 3 bits are used as magnitude bits when irregular quantization is used, LDPC codes provide good performance. Therefore, the method according to the present invention may be more effective for LDPC codes.

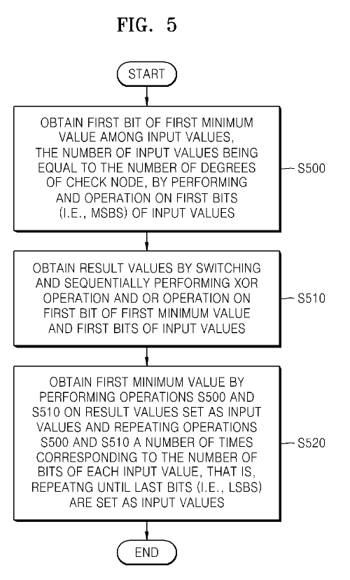

FIG. 5 is a flowchart illustrating a method of updating a check node for a LDPC code, according to an embodiment of the present invention.

In operation S500, a first bit of a first minimum value among input values, the number input values being equal to the number of degrees of the check node, is obtained by performing an AND operation on first bits (i.e., MSBs) of the input values.

In operation S510, result values are obtained by switching and sequentially performing an XOR operation and an OR operation on the first bit of the first minimum value and each of the first bits of the input values. In operation S520, operations S500 and S510 are performed again on the result values set as input values, and operations S500 and S510 are performed a number of times corresponding to the number of bits of each input value, that is, operations S500 and S510 are performed until last bits (i.e., LSBs) are set as input values, thereby obtaining the first minimum value.

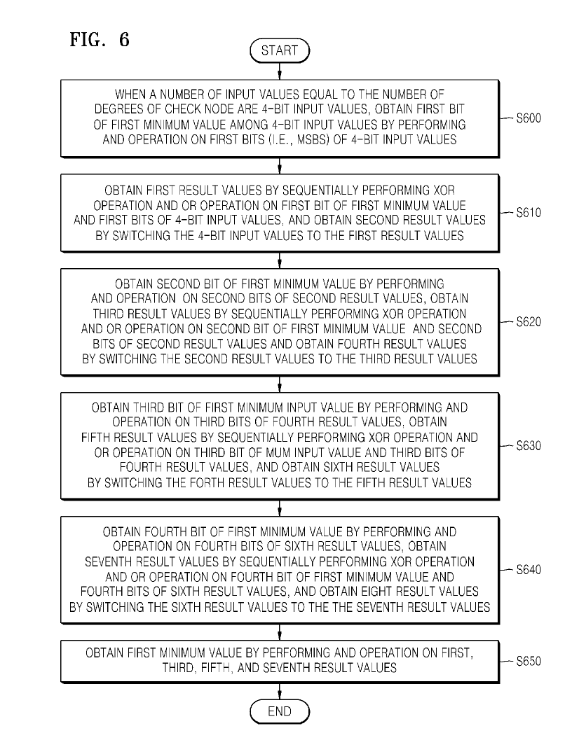

FIG. 6 is a flowchart illustrating a method of updating a check node for a LDPC code when a number of input values equal to the number of degrees of the check node are 4-bit input values, according to an embodiment of the present invention.

In operation S600, when a number of input values equal to the number of degrees of the check node are 4-bit input values, a first bit of a first minimum value among the 4-bit input values is obtained by performing an AND operation on first bits (i.e., MSBs) of the 4-bit input values.

In operation S610, an XOR operation and an OR operation are sequentially performed on the first bit of the first minimum value and each of the first bits of the 4-bit input values in order to obtain first result values, and second result values are obtained by switching the 4-bit input values to the first result values.

In operation S620, a second bit of the first minimum value is obtained by performing an AND operation on second bits of the second result values, an XOR operation and an OR operation are sequentially performed on the second bit of the first minimum value and the second bit of each of the second result values in order to obtain third result values, and fourth result values are obtained by switching the second result values to the third result values.

In operation S630, a third bit of the first minimum value is obtained by performing an AND operation on third bits of the fourth result values, an XOR operation and an OR operation are sequentially performed on the third bit of the first minimum value and the third bit of each of the fourth result values in order to obtain fifth result values, and sixth result values are obtained by switching the fourth result values to the fifth result values.

In operation S640, a fourth bit of the first minimum value is obtained by performing an AND operation on fourth bits of the sixth result values, an XOR operation and an OR operation are sequentially performed on the fourth bit of the first minimum value and the fourth bit of each of the sixth result values in order to obtain seventh result values, and eighth result values are obtained by switching the sixth result values to the seventh result values.

In operation S650, the first minimum value is obtained by performing an AND operation on the first, third, fifth, and seventh result values.

As described above, the present invention provides an apparatus and method for obtaining a first minimum input value and a second minimum input value among several input values while linearly increasing only the complexity with an increase in the degree of a check node and not increasing the processing speed when a check node of a LDPC decoder is updated using a Min-Sum algorithm, an Offset Min-Sum algorithm, or a Normalized Min-Sum algorithm. Accordingly, as compared with the conventional art, the check node update according to the present invention reduces the complexity of hardware and provides super high-speed processing.

Moreover, the check node update according to the present invention is applicable to not only the field of LDPC code decoding but also all fields that require a function of searching a minimum input value.

The invention can also be embodied as computer readable codes on a computer readable recording medium. The computer readable recording medium is any data storage device that can store data which can be thereafter read by a computer system. Examples of the computer readable recording medium include read-only memory (ROM), random-access memory (RAM), CD-ROMs, magnetic tapes, floppy disks, optical data storage devices, and carrier waves (such as data transmission through the Internet). The computer readable recording medium can also be distributed over network coupled computer systems so that the computer readable code is stored and executed in a distributed fashion.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of updating a check node of a low-density parity check (LDPC) code in order to decode the LDPC code, the method comprising:
(a) obtaining a first bit of a first minimum value among input values, the number of input values being equal to the number of degrees of the check node, by performing an AND operation on first bits of the input values, the first bits being most significant bits of the input values;
(b) obtaining result values by switching and sequentially performing an XOR operation and an OR operation on the first bit of the first minimum value and each of the first bits of the input values; and
(c) performing operations (a) and (b) on the result values set as input values and performing operations (a) and (b) a number of times corresponding to the number of bits of each input value, that is, repeating until last bits are set as input values, to thereby obtain the first minimum value, the last bits being least significant bits of the input values.

2. The method of claim 1, wherein the first minimum value is set as a maximum input value, and a second minimum value is obtained by repeating operations (a), (b), and (c).

3. The method of claim 1, wherein operations (a), (b), and (c) are repeated until a number of minimum values corresponding to the number of degrees of the check node are obtained.

4. The method of claim 1, wherein, when the check node is a check node for a row-split parity check matrix, operations (a), (b), and (c) are repeated until a number of minimum values corresponding to the number of degrees of each of the check node and another check node for a row-split parity check matrix are obtained.

5. The method of claim 1, wherein, when the input values are 4-bit input values, operation (a) comprises obtaining the first bit of the first minimum input value among the 4-bit input values by performing an AND operation on the first bits of the 4-bit input values, the first bits being most significant bits of the 4-bit input values, and operation (b) comprises obtaining first result values by sequentially performing an XOR operation and an OR operation on the first bit of the first minimum value, and each of the first bits of the 4-bit input values and obtaining second result values by switching the 4-bit input values to the first result values.

6. The method of claim 5, wherein operation (c) of claim 1 comprises:
(c1) obtaining a second bit of the first minimum value among the 4-bit input values by performing an AND operation on second bits of the second result values; and
(c2) obtaining third result values by sequentially performing an XOR operation and an OR operation on the second bit of the first minimum input value and the second bit of each of the second result values, and obtaining fourth result values by switching the second result values to the third result values.

7. The method of claim 6, wherein operation (c) further comprises:
(c3) obtaining a third bit of the first minimum value among the 4-bit input values by performing an AND operation on third bits of the fourth result values; and
(c4) obtaining fifth result values by sequentially performing an XOR operation and an OR operation on the third bit of the first minimum value and the third bit of each of the fourth result values, and obtaining sixth result values by switching the fourth result values to the fifth result values.

8. The method of claim 7, wherein operation (c) further comprises:
(c5) obtaining a fourth bit of the first minimum value among the 4-bit input values by performing an AND operation on fourth bits of the sixth result values; and
(c6) obtaining seventh result values by sequentially performing an XOR operation and an OR operation on the fourth bit of the first minimum value and the fourth bit of each of the sixth result values, and obtaining eighth result values by switching the sixth result values to the seventh result values.

9. The method of claim 8, wherein operation (c) further comprises (c7) obtaining the first minimum value by performing an AND operation on the first, third, fifth, and seventh result values.

10. The method of claim 5, further comprising (d) obtaining a second minimum value by setting as 4-bit input values, the number of 4-bit input values being equal to the number of degrees of the check node in operation (a), values obtained by switching the 4-bit input values to results of NOT operations performed on the first minimum value and by re-performing operations (a), (b), and (c).

11. The method of claim 5, when the check node is a check node for a row-split parity check matrix, further comprising:
obtaining a first minimum value and a second minimum value among 4-bit input values for another row-split check node, the number of 4-bit input values equal to the number of degrees of the another row-split check node, by performing operations (a), (b), and (c) on the 4-bit input values; and
obtaining a minimum value for each of the two check nodes from the first and second minimum values among the 4-bit input values for each of the two check nodes.

12. An apparatus for updating a check node of a low-density parity check (LDPC) code in order to decode the LDPC code, the apparatus comprising:
a first bit processor obtaining a first bit of a first minimum input value among 4-bit input values, the number of which is equal to the number of degrees of the check node, by performing an AND operation on first bits of the 4-bit input values, the first bits being most significant bits (MSB) of the 4-bit input values, obtaining first result values by sequentially performing an XOR operation and an OR operation on the first bit of the first minimum value and each of the first bits of 4-bit input values, and obtaining second result values by switching the 4-bit input values to the first result values;
a second bit processor obtaining a second bit of the first minimum value among the 4-bit input values by performing an AND operation on second bits of the second result values, obtaining third result values by sequentially performing an XOR operation and an OR operation on the second bit of the first minimum value and the second bit of each of second result values, and obtaining fourth results by switching the second result values to the third result values;
a third bit processor obtaining a third bit of the first minimum value among the 4-bit input values by performing an AND operation on third bits of the fourth result values, obtaining fifth result values by sequentially performing an XOR operation and an OR operation on the third bit of the first minimum value and the third bit of each of the fourth result values, and obtaining sixth result values by switching the fourth result values to the fifth result values;
a fourth bit processor obtaining a fourth bit of the first minimum input value among the 4-bit input values by performing an AND operation on fourth bits of the sixth result values, obtaining seventh result values by sequentially performing an XOR operation and an OR operation on the fourth bit of the first minimum value and the fourth bit of each of the sixth result values, and obtaining eighth result values by switching the sixth result values to the seventh result values; and
a bit minimum value calculator obtaining the first minimum value by performing an AND operation on the first, third, fifth, and seventh result values.

13. The apparatus of claim 12, wherein a second minimum value is obtained by setting, as the 4-bit input values in the first bit processor, values obtained by switching the 4-bit input values to results of NOT operations performed on the first minimum value obtained in the bit minimum value calculator.

14. The apparatus of claim 13, further comprising a node minimum value calculator which, when the check node is a check node for a row-split parity check matrix, calculates a minimum value for each of the check node and another row-split check node by using first and second minimum values of 4-bit input values for each of the two check nodes, wherein the first and second minimum values of the 4-bit input values for the another check node, the number of which is equal to the number of degrees of the another row-split check node, are obtained by setting the 4-bit input values as the input values of the first bit processor.
